(19) United States
(12) Patent Application Publication
(10) Pub. No.: US 2004/0057198 A1
(43) Pub. Date: Mar. 25, 2004

(54) Device housing comprising an electromagnetically shielded region

(76) Inventors: Helmut Kahl, Berlin (DE); Bernd Tiburtius, Kleinmachnow (DE)

Correspondence Address: Patrick W. Rasche, Armstrong Teasdale LLP, Suite 2600, One Metropolitan Sq., St. Louis, MO, 63102, US

(21) Appl. No.: 10/386,151

(22) Filed: Mar. 11, 2003

(30) Foreign Application Priority Data
Mar. 11, 2002 (DE) 102 10 578.2

(51) Int. Cl. H05K 5/00

(52) U.S. Cl. 361/683

(57) ABSTRACT

Device housing designed to enclose an electronic device and incorporating an electromagnetically shielded three-dimensional region, which comprises at least one shielding wall constructed by dispensing onto a substrate a plurality of substantially superimposed, and in particular fused to form a material unit, beads of an elastomer or soft plastic, or by dispensing a single, tall elastomer or soft-plastic bead with a height at least twice its width, wherein the elastomer or soft plastic is filled so as to be electrically conductive and/or the shielding wall as a whole has a conductive coating.

### DESCRIPTION

The invention relates to a housing that is designed to enclose an electronic device and incorporates an electromagnetically shielded space to accommodate components that either emit interfering electromagnetic radiation or are vulnerable to such radiation.

At present the great majority of such device housings are injection-molded from plastic and subsequently metallized at least in part—predominantly by galvanic methods—to endow them with the surface conductivity required to obtain the necessary EMI-shielding action. At the abutting edges of housings constructed of more than one part, sealing elements with an EMI shielding action (also called shielding gaskets) are provided so as to ensure that the housing provides uninterrupted shielding. Such shielding gaskets can be manufactured separately and inserted into or glued onto, the relevant edge regions, or they are formed in place by means of a suitable shaping tool (FIPG method). Finally, it has been known for some time that such shielding gaskets can be produced in situ both between different parts of a housing and between housing parts and circuit boards, being applied by means of a needle or nozzle guided under computer control and allowed to cure under ambient conditions before the housing is closed or the parts are connected to one another. For the state of the art regarding this last type of shielding gasket, reference is made to the documents EP 0 629 114 B1, EP 0 654 962 B1, WO 98/06246, WO 98/08365 and WO 01/99483.

A related method also known, for instance from EP 0 629 114 B1, is to build up shielding gaskets in several layers, by repeatedly applying sealing material to one and the same part of the housing by means of the above-mentioned dispenser needles or nozzles; by this means even relatively complicated gasket profiles can be produced, to allow for special structural requirements.

It is the objective of the invention to disclose a further improved device housing of the kind in question here, which is simple and economical to manufacture and is versatile enough to be adapted to altered structural specifications.

This objective is achieved by a device housing with the characteristics given in claim 1.

Advantageous further developments of the idea underlying the invention are the subject of the dependent claims.

The invention includes the essential idea of using the dispensing procedure known per se to produce an actual “shielding wall”, i.e. a wall forming part of the housing that itself has an EMI-shielding action, instead of having to shape a shielding element in advance with a form tool for a primary shaping process (injection or pressure molding) or deformation (deep-drawing or the like). In addition, the invention includes the idea that the material employed to construct this shielding wall is selected such that the shielding wall can either be produced in a single operation with a stable form such that its height is at least twice its width, or be built up from several beads of material stacked substantially one on top of another so as to result in a largely dimensionally stable structure. Finally, another idea belonging to the invention is that the dispensing procedure should be carried out in a manner adapted to such a construction, with respect to the cross-section of the dispensed material as well as to the dispensing rate and other parameters such as the duration of the pauses between successive applications, distance of the needle from the receiving surface, temperature during the procedure etc.

The invention describes an economical way to produce a shielding for part of the space within a housing or shielding for an entire housing. The solution reduces the manufacturing times, and hence the costs, in comparison to the ways of “molding EMI gaskets” that are currently on the market.

In contrast to previous gaskets comprising conductive material that are “molded” by application to carrier materials such as simple metal sheets or metallized plastic substrates, the invention does not depend on any tool for determining the gasket geometry.

As a result, for instance, it is possible to shape the outer wall of a shielding cap, and even internal ribbed structures are simple to form by this means.

The dispensed material produces the wall surfaces that delimit a three-dimensional space within which are accommodated the electronic component(s) that should be shielded (where appropriate including printed circuitry).

It is also possible to produce gaskets with height that varies in accordance with the geometry of the substrate (whether made of sheet metal, cast metal or metallized plastic), so that the “shielding walls” of the shield element can be adapted to special local features.

In a special embodiment of the invention the shielding walls are formed by dispensing an elastomer that is not electrically conductive, i.e. thermoplastic or duroplastic plastics/elastomers, and subsequently providing them with an electrically conductive surface formed by electrically conductive lacquers, which are applied by electroplating, sputtering, vacuum coating or spraying.

The substrate can in general consist of an insulating film (greater than 1 μm) or be metallized or even be made entirely of metal, ranging to rigid substrates such as housings (plastic/metal) with a mechanical carrier function. Here, again, shielding walls in accordance with the invention are possible. A combination with conventionally formed, sprayed-on, injected or mechanically shaped walls is possible.

The relevant parts of the housing can be fixed in position in various direct or indirect ways, as best facilitates construction, e.g. by pressing-on, by means of screws or adhesive, by snap systems etc.

In a first preferred embodiment of the invention the three-dimensional region concerned is substantially entirely enclosed by a shielding wall made of stacked beads of elastomer or soft plastic, or by a single, tall bead of elastomer or soft plastic. The region to be shielded can thus be specified entirely under software control, by suitable guidance of the dispensing needle or needles. An alternative possibility, of course, is combination with shielding-wall sections produced by injection molding or another prior shaping or deformation procedure, employing an appropriate form tool.

In another useful embodiment of the invention at least one shielding wall made of stacked beads of elastomer or soft plastic, or of the tall bead of elastomer or soft plastic, in particular the entire shielded region, is positioned in the interior of the encased device. In combination herewith, or as an alternative hereto, at least one shielding wall made of stacked beads of elastomer or soft plastic, or of the tall bead of elastomer or soft plastic, forms part of an outer wall of the device. Altogether the invention advantageously enables several shielded spaces to be enclosed by shielding walls that abut against one another, by which means the structural demands imposed by complex, multifunctional electronic devices (e.g., combined mobile telephone/PDA) can be taken into account in a flexible manner.

In an embodiment suitable for miniaturized electronic devices of modern construction, the shielding wall or at least one of the shielding walls is composed of at least three, preferably five or more beads and is at least 2 mm high. It should be understood that the height of the shielding wall can also be greater, so as to adapt it to the electronic components that are to be accommodated in the shielded regions, or—as the exemplary embodiments will make still clearer—wall sections of different heights and various constructions can be combined with one another in a single device housing.

Furthermore, the substrate and/or a cover for the shielded three-dimensional region is made of metal, in particular thin, flexible sheet metal, which is supported in such a way as to maintain substantially continuous linear contact between the shielding wall and the cover. Alternatively thereto, or in combination therewith, the substrate or one of the substrates and/or a cover for the shielded space consists of a metallized plastic plate or film, which is supported in such a way as to maintain substantially continuous linear contact between the shielding wall and the cover. With these variants, the most diverse modern electronic devices can be provided with housings that can be modified in practically any desired manner to suit both the mechanical and the electromagnetic requirements of the device concerned.

In another useful embodiment the substrate or a cover for the shielded space is constructed as a printed circuit board with electronic components. This variant takes into account the fact that in miniaturized electronic devices of modern construction the printed circuits or other component carriers often also function as mechanical elements of the housing that encloses the device.

The electrical conductivity needed for EMI shielding is achieved in a first variant by using an elastomer or soft plastic that is filled with metal and/or carbon particles. Another variant provides for the shielding wall to be covered on at least one side by a conductive thin layer, in particular one applied by vapor deposition, spraying or sputtering, which extends to the substrate and thereby causes the substrate and shielding wall to act as an uninterrupted shield structure. The two variants can also be combined, in any case for special applications that present particularly severe demands with regard to the EMI-shielding action.

In another embodiment of the invention it is provided that at least one shielding wall is made of a single, tall elastomer or soft-plastic bead and at least one other shielding wall is formed by a plurality of elastomer beads disposed above one another. Hence one and the same procedure can be used, and a single material employed, to construct shielding walls or shielding gasket regions with distinctly different heights, as a result of which by simple means and in an economical manner a high degree of flexibility in the housing construction can be attained.

Devices of the kind concerned here are in particular mobile wireless terminals or other telecommunications terminals or components of mobile wireless networks (in particular base stations) that constitute a source of EMI or are vulnerable thereto, as well as EMI-sensitive data-communication or data-processing devices and parts thereof. Devices used in the areas of sensing systems, operational measurement and process-control technology, radio navigation and the like are also relevant here.

Further advantages and useful features of the invention will be evident from the following description, in brief outline, of preferred exemplary embodiments and aspects. The figures are as follows:

FIG. 1 a schematic drawing of part of a housing according to one embodiment of the invention, in side view,

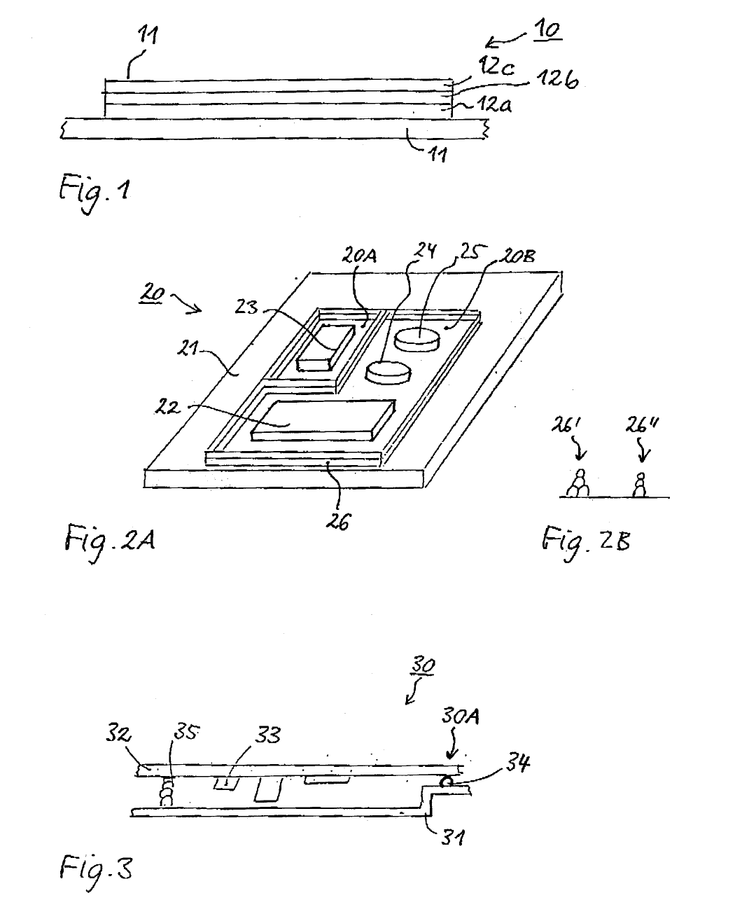

FIG. 2A a (likewise schematic) perspective drawing of another embodiment,

FIG. 2B cross-sectional drawings of advantageous shielding-wall or shielding-gasket profiles,

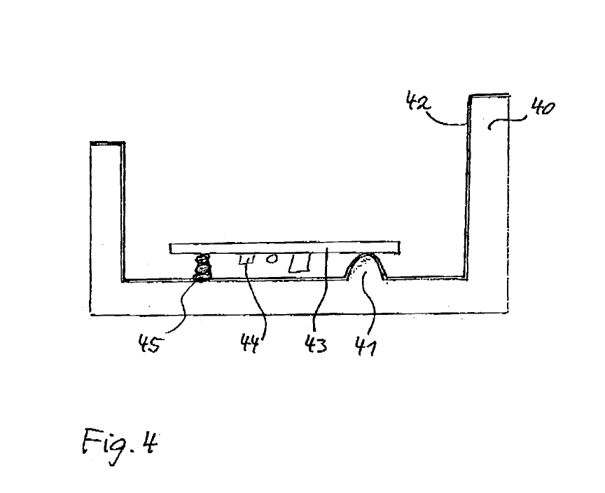

FIGS. 3 and 4 schematic drawings of other embodiments of the invention in the form of side views or cross-sectional drawings,

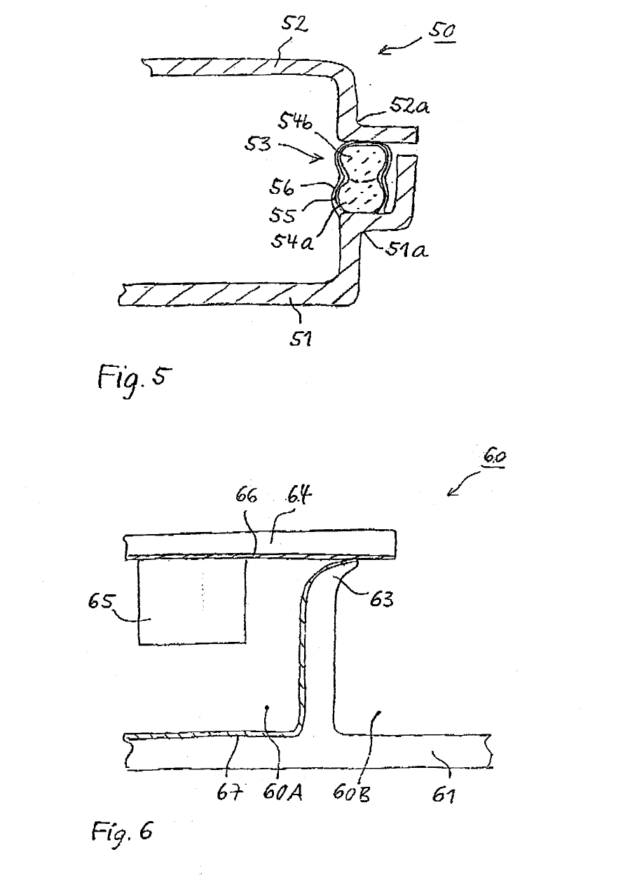

FIG. 5 a schematic cross-sectional drawing of a device housing according to a first embodiment of the invention, and

FIG. 6 a schematic cross-sectional-drawing of a device housing according to a second embodiment of the invention.

FIG. 1 is a diagram to show the structure of a part 10 of a housing to shield an EMI-sensitive electronic device, in which to a flat substrate 11 (e.g., an undistorted piece of sheet metal or a metallized plastic plate) there has been applied, by a dispensing procedure known per se, a three-bead profile 12 made of an elastomer or soft plastic filled with a conductive material. The profile 12 has been formed by guiding a dispensing needle or nozzle over the substrate 11 three times, each time using the same XY coordinates but lifting the dispensing tool by a prespecified amount corresponding approximately to the height of the bead applied during the preceding step. Thus the profile comprises three, substantially equally high beads of material 12a, 12b, 12c. As an alternative to a conductive filling, the three-bead profile can also be made of an unfilled elastomer or soft plastic and subsequently provided with a conductive coating (thin layer).

FIG. 2A shows in schematic perspective a component 20 of an electronic device, in which on a substrate 21 (here in particular a printed circuit board) several electronic components 22 to 25 are disposed, distributed in two regions 20A and 20B that are electromagnetically separate from one another and individually shielded.

On sides of the substrate 21 the shielding is ensured by a metallic coating applied thereto (not shown). The ridges enclosing the shielded regions 20A, 20B constitute a shielding gasket 26 with the shape shown in the figure, which has been formed by application from a dispenser in two layers. The shielding is completed by a housing part (not shown in the figure) that is placed on the shielding gasket 26 and has a shielding action, being made e.g. of metal or having a metallized surface.

In FIG. 2B are diagrammed two profiles of modified, three- and four-part shielding gaskets 26′ and 26″, respectively, which serve as replacements for the shielding gasket 26 according to FIG. 2A when a greater height is needed. Here the three-part profile on the right side of FIG. 2B is somewhat easier to produce, whereas the four-part profile 26′ on the left side of the figure, with two beads side by side at its base, requires somewhat greater effort but satisfies distinctly higher stability requirements.

FIG. 3 shows a cross-sectional representation (in a diagrammatic form similar to that in FIGS. 1 to 2B) of part of a device housing 30 with lower part 31 having a generally basin-like shape and a substantially flat lid 32 that contains electronic components 33. In an outer-edge region 30A is an outer-edge gasket 34 of the conventional kind, applied from a dispenser, whereas in the interior of the device housing 30 an internal shielding wall 35 has been built up from four beads of the same elastomer or soft plastic that was used for the outer-edge gasket 34. The latter can advantageously be produced in such a way that it is continuous with one of the beads that forms the shielding wall 35, to ensure that there are no gaps in the EMI shielding around the edge of the part of the housing within which the electronic components 33 are disposed.

FIG. 4 shows another embodiment of a compartment 40 of a housing for an electronic component, which here has a U-shaped cross section and is made of a relatively soft plastic material; on the floor of this compartment a sealing ridge 41 has been formed from the same material so as to be integral therewith. The inner surface of the housing, including the edge regions and the sealing ridge 41, is provided with a metallic coating 42. A circuit board 43 bearing electronic components is supported, near one of its side edges, on the sealing ridge 41. Near its opposite edge, the board 43 is supported on the floor of the compartment 40 by a three-bead profile 45 of the kind shown in side view in FIG. 1. The profile 45 is designed to serve as a shielding profile, being-filled with conductive material and together with the metallic coating 42 of the housing compartment and a similar coating (not shown) of the board 43 forms an EMI-shielded-space to contain the components 44.

FIG. 5 shows part of a device housing 50 made of metal, e.g. deep-drawn A1 sheet, comprising a lower housing shell 51 and an upper housing shell 52, which are connected to one another by fixation means not shown in the drawing (for example, screws or a catch fastener). In an edge region of the housing 50, where the lower and upper housing shells 51, 52 each have an outwardly bent region 51a or 52a, a shielding element in the form of an outer housing gasket 53 is inserted between the shells.

The outer housing gasket 53 is composed of two elastomer beads 54a, 54b dispensed onto the outwardly bent region 51a of the lower housing shell 51. Of these two beads, the lower one 54a adheres fixedly to the surface of the lower housing shell 51, while the upper elastomer bead 54b is fused to the lower bead 54a as a result of having been applied immediately after the latter was formed. Onto the base gasket profile 54a/54b thus formed two layers have been applied, first a thin copper layer, as a highly conductive basal layer, and then a covering layer 56 made of a tin alloy with low lead content; each layer is applied by a high-vacuum coating method. The thicknesses of the basal layer 55 and covering layer 56 are such as to obtain on one hand the necessary deformability of the outer housing gasket 53, and on the other hand its shielding action; depending on the intended use of the housing 50, resistance to environmental influences (moisture, salt water etc.) should also be taken into account.

FIG. 6 shows a schematic cross section of part of a housing 60 made of a thermoplastic polymer by injection molding; the drawing shows only that part of the housing-bottom 61 that includes a vertically upright partition 62. The partition 62 separates a housing region 60A, which is to be shielded from EMI, from a second housing region 60B, so that the two regions are sealed off from one another both mechanically and electromagnetically. On the upper edge of the partition 62, which is tapered in cross section to form a flexible sealing lip 63, lies a circuit board 64 with electronic components, to symbolize which an EMI-sensitive component 65 is shown here.

In the upward direction the first housing region 60A is substantially tightly sealed by a conductive surface coating 66 on the circuit board 64. Downward and toward the side the electromagnetic shielding is ensured by tin-alloy layer 67 that has been applied to the whole surface of the left-hand section of the housing bottom 61 and the adjoining (left) surface of the partition 62.

The implementation of the invention is not restricted to the examples described above but is also possible in a large number of further modifications and in particular combinations of the aspects described here, which are within the competency of a person skilled in the art.

List of reference numerals

| | |
|---|---|
| 10 | Part of housing |
| 11 | Substrate |
| 12; 45 | Three-bead profile |
| 12a, 12b, 12c | Dead of material |
| 20 | Component |
| 20A, 20B | Shielded space |
| 21 | Substrate |
| 22, 23, 24, 25 | Component |
| 26; 26′, 26″ | Shielding gasket |
| 30 | Device housing |
| 31 | Compartment |
| 32 | Lid |
| 33 | Component |
| 34 | Outer-edge gasket |
| 35 | Shielding wall |
| 40 | Housing compartment |
| 41 | Sealing ridge |
| 42 | Metallic coating |
| 43 | Circuit board |
| 44 | Component |
| 50; 60 | Housing |
| 51; 61 | Lower housing shell |
| 51a | Outward bend |
| 52 | Upper housing shell |
| 52a | Outward bend |
| 53 | Housing gasket (shielding gasket) |
| 54a, 54b | Elastomer bead |
| 54a/54b | Base gasket profile |
| 55 | Thin copper layer (basal layer) |
| 56; 67 | Tin-alloy layer (covering layer) |
| 60A, 60B | Housing region |
| 62 | Partition |
| 63 | Sealing lip |
| 64 | Circuit board |
| 65 | Component |
| 66 | Surface coating |

1. Device housing designed to enclose an electronic device and incorporating an electromagnetically shielded three-dimensional region, which comprises at least one shielding wall constructed by dispensing onto a substrate a plurality of substantially superimposed, and in particular fused to form a material unit, beads of an elastomer or soft plastic, or by dispensing a single, tall elastomer or soft-plastic bead with a height at least twice its width, wherein the elastomer or soft plastic is filled so as to be electrically conductive and/or the shielding wall as a whole has a conductive coating.

2. Device housing according to claim 1,
characterized in that the three-dimensional region is enclosed on substantially all sides by a shielding wall consisting of superimposed elastomer or soft-plastic beads or of the tall elastomer or soft-plastic bead.

3. Device housing according to claim 1 or 2,
characterized in that at least one shielding wall made of elastomer or soft-plastic beads or of the tall elastomer or soft-plastic bead, in particular the entire shielded space, is within the interior of the device.

4. Device housing according to one of the preceding claims, characterized in that at least one shielding wall made of elastomer or soft-plastic beads or of the tall elastomer or soft-plastic bead forms an outer wall section of the device.

5. Device housing according to one of the preceding claims, characterized in that the or at least one shielding wall comprises at least three, preferably five or more beads and is at least 2 mm high.

6. Device housing according to one of the preceding claims, characterized by several shielded three-dimensional regions surrounded by shielding walls that abut against one another.

7. Device housing according to one of the preceding claims, characterized in that the substrate and/or a cover of the shielded three-dimensional region consists of metal, in particular a thin, flexible metal sheet, which is held in such a way that a substantially continuous linear contact between the shielding wall and the cover is produced.

8. Device housing according to one of the preceding claims, characterized in that the substrate and/or a cover of the shielded three-dimensional region is made of a metallized plastic plate or film, which is held in such a way that a substantially continuous linear contact between the shielding wall and the cover is produced.

9. Device housing according to one of the preceding claims, characterized in that the substrate or a cover of the shielded three-dimensional region is constructed as a circuit board with electronic components.

10. Device housing according to one of the preceding claims, characterized in that the elastomer or the soft plastic is filled with metal and/or carbon particles.

11. Device housing according to one of the preceding claims, characterized in that the shielding wall is covered on at least one side by a conductive thin layer, in particular one that has been applied by vapor deposition, spraying or sputtering, which extends as far as the substrate so that substrate and shielding wall together have an uninterrupted shielding action.

12. Device housing according to one of the preceding claims, characterized in that at least one shielding wall is made of a single, tall elastomer or soft-plastic bead and at least one other shielding wall is formed by a plurality of superimposed elastomer beads.

13. Device with a housing according to one of the preceding claims, characterized by being designed as a telecommunications or data-communication device.
